(19) United States
(12) Patent Application Publication
(10) Pub. No.: US 2005/0105264 A1
(43) Pub. Date: May 19, 2005

(54) Notebook computer with a hanging type display screen

(75) Inventor: Ching-Jou Chen, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 10/972,395

(22) Filed: Oct. 26, 2004

(30) Foreign Application Priority Data
Nov. 14, 2003 (TW) 092220231

(51) Int. Cl. H05K 7/00

(52) U.S. Cl. 361/683

(57) ABSTRACT

A notebook computer having a base member, which has a keyboard and a front extension portion with a plurality of locating holes, and a display cover formed of a cover shell and a display screen, and pivotally connected to the base member and turnable relative to the base member between an open position and a close position. The cover shell defines a recessed receiving open chamber. The display screen has a top side pivoted to the cover shell such that the display screen is turnable in and out of the recessed receiving open chamber, and a bottom side provided with protruding positioning members for positioning in the locating holes after the display screen has been turned out of the recessed receiving open chamber.

### BACKGROUND OF THE INVENTION

1. Field of the Invention

The present invention relates to a notebook computer and more particularly, to a notebook computer with a hanging type display screen, which allows the user to adjust the display screen to one of a series of angular positions.

2. Description of Related Art

In a conventional notebook computer as shown in FIG. 1, the display screen 100 and the display cover 110 are fixedly fastened together and then pivoted to the base member 120. Following fast development of computer technology, the display screen of a notebook computer provides multiple functions including touch control or handwrite function. However, due to limited operation angle of the display screen 100, the user may feel uncomfortable when using the touch control or handwrite function of the display screen 100. Recently, various improved display screen designs for notebook computer have been disclosed. In general, a folding dual-screen type notebook computer, which allows the user to adjust the tilting angle of the display screens by means of a rack. Another prior art, a notebook computer with a swivel display screen, which uses a gyrostat for enabling the display screen to be turned upside down. However, these conventional skills do not allow the display screen to be positioned with its bottom side on the base member or extended to the outside of the display cover and the base member.

### SUMMARY OF THE INVENTION

The present invention has been accomplished under the circumstances in view. It is therefore the main object of the present invention to provide a notebook computer, which has a simple structure and, which allows the user to conveniently adjust the tilting angle of the display screen subject to the desired visual angle.

To achieve this and other objects of the present invention, the notebook computer comprises a base member and a display cover pivotally connected to the base member and turnable relative to the base member between an open position and a close position. Wherein, the base member comprises a keyboard, and a front extension portion, which comprises a plurality of locating holes. The display cover comprises a cover shell, which defines a recessed receiving open chamber, and a display screen, which has a top side and a bottom side. The top side of the display screen is pivoted to the cover shell such that the display screen is turnable in and out of the recessed receiving open chamber.

Preferably, the bottom side of the display screen is provided with protruding positioning members for positioning in the locating holes. The quantities of the protruding positioning member and the locating hole are not restricted. Preferably, the quantity of the protruding positioning member is equal to that of the locating hole. The top side of the display screen is smoothly chamfered for convenient adjustment of the angular position of the display screen. Further, the display screen is turnable out of the recessed receiving open chamber to the outside of the base member and the cover shell.

### BRIEF DESCRIPTION OF THE DRAWINGS

FIG. 1 is a perspective view of a conventional notebook computer.

FIG. 2 is a perspective view of a notebook computer with a hanging type display screen according to the present invention.

FIG. 3 is a sectional view in an enlarged scale of the upper part of the display cover, showing the display screen turned out of the recessed receiving open chamber.

FIG. 4 shows one application example of the notebook computer according to the present invention.

FIG. 5 shows another application example of the notebook computer according to the present invention.

FIG. 6 shows still another application example of the notebook computer according to the present invention.

### DETAILED DESCRIPTION OF THE PREFERRED EMBODIMENT

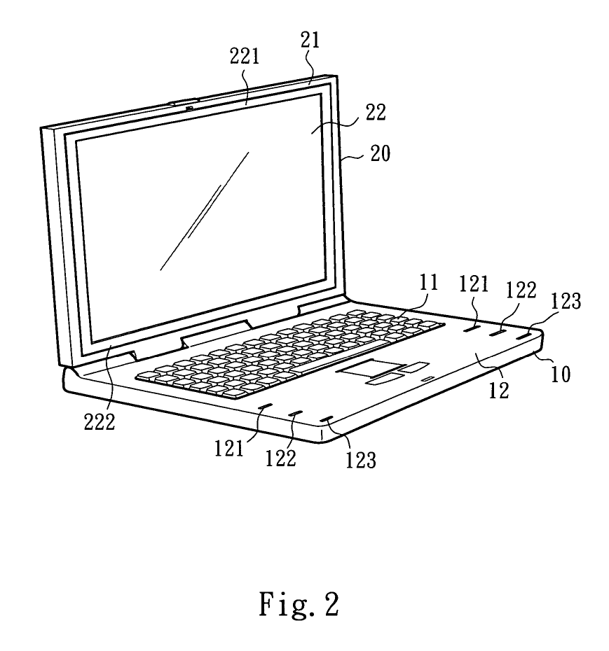

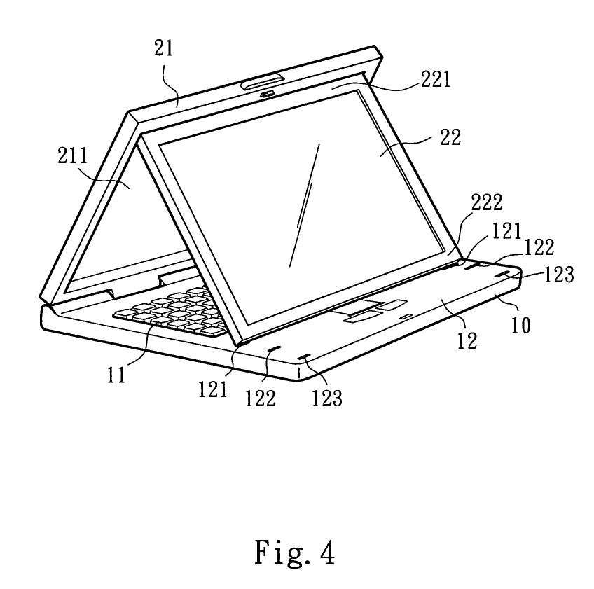

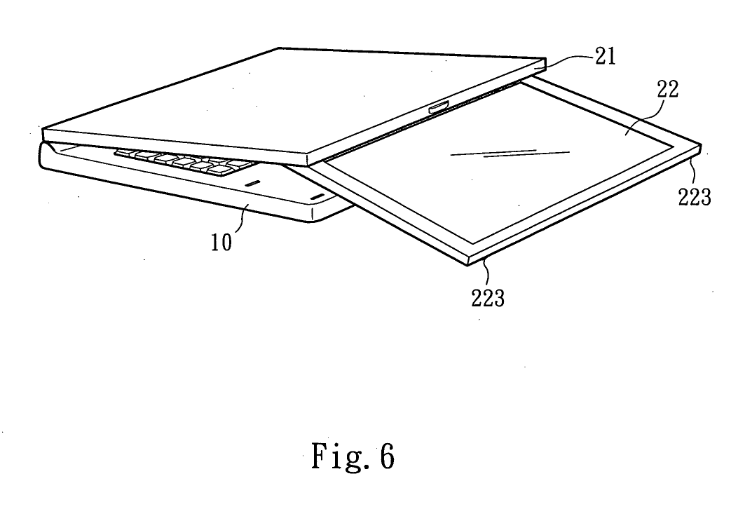

Referring to FIG. 2, a notebook computer is shown including a base member 10 and a display cover 20. The display cover 20 is pivotally connected to the base member 10, and can be opened from the base member 10 or closed on the base member 10. The base member 10 has a keyboard 11 and an extension portion 12. Three sets of locating holes 121,122,123 are formed in the extension portion 12. The display cover 20 has a cover shell 21 and a display screen 22. The cover shell 21 defines a recessed receiving open chamber 211 (see FIG. 4) adapted to accommodate the display screen 22. The display screen 22 has a top side 221 and a bottom side 222. The top side 221 of the display screen 22 is pivoted to the cover shell 21. The bottom side 222 of the display screen 22 is provided with a plurality of protruding positioning members 223 (see FIG. 6) for positioning in the locating holes 121 in the extension portion 12 of the base member 10.

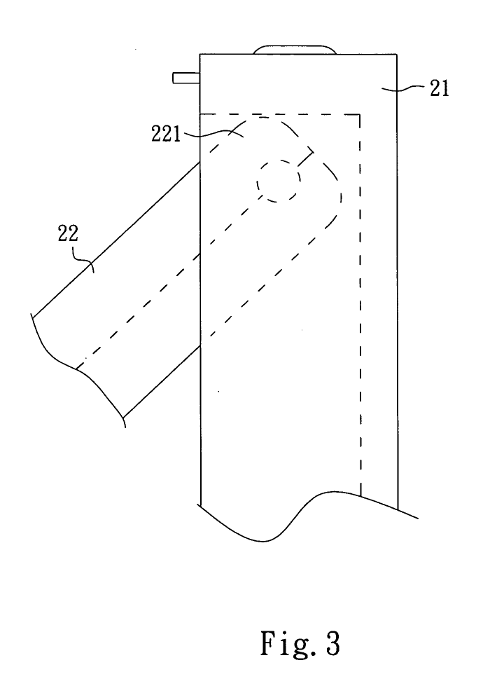

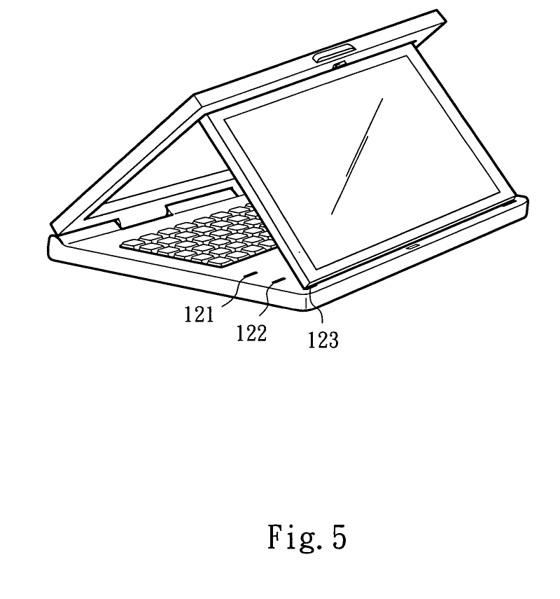

Referring to FIG. 3, the top side 221 of the display screen 22 is smoothly chamfered for easy adjustment of the position of the display screen 22. For example, when the user wishes to use a device on the display screen 22 such as touch control or handwrite device for data entry instead of the keyboard 11, the user can then turn the bottom side 222 of the display screen 22 out of the recessed receiving open chamber 211 of the cover shell 21 and then force the protruding positioning members 223 into the locating holes 121 in the extension portion 12 of the base member 10 as shown in FIG. 4, and the user can thus conveniently use the display screen 22 for data entry. Further, the tilting angle of the display screen 22 is adjustable. For example, the user can shift the protruding positioning members 223 from the rear-sided locating holes 121 to the middle locating holes 122 to increase the tilting angle of the display screen 22, or to the front-sided locating holes 123 to increase the tilting angle of the display screen 22 further, as shown in FIG. 5. If desired, the user can extend the display screen 22 out of the cover shell 21 and the base member 10 and rested the display screen 22 on the upper side of table where the notebook computer is placed as shown in FIG. 6.

As indicated above, the notebook computer with a hanging type display screen has a simple structure, and provides a broad display screen adjustment angle. The user can conveniently adjust the angular position of the display screen according to the desired visual angle, or put the display screen on the upper side of table in about a horizontal position for writing or use.

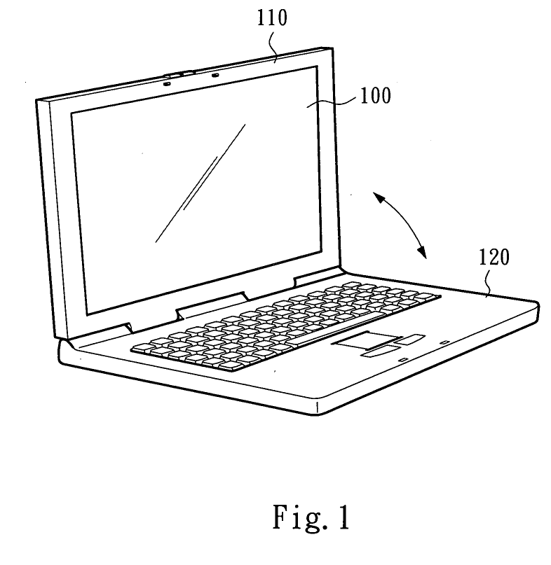

A prototype of notebook computer with a hanging type display screen has been constructed with the features of FIGS. 1˜6. The notebook computer with a hanging type display screen functions smoothly to provide all of the features discussed earlier.

Although the present invention has been explained in relation to its preferred embodiment, it is to be understood that many other possible modifications and variations can be made without departing from the spirit and scope of the invention as hereinafter claimed.

1. A notebook computer comprising a base member and a display cover pivotally connected to said base member and turnable relative to said base member between an open position and a close position, wherein said base member has a keyboard and a front extension portion, said front extension portion having a plurality of locating holes; and said display cover has a cover shell, said cover shell defining a recessed receiving open chamber, and a display screen, said display screen having a top side and a bottom side, said top side being pivoted to said cover shell such that said display screen is turnable in and out of said recessed receiving open chamber.

2. The notebook computer as claimed in claim 1, wherein said display screen has a plurality of protruding positioning members extended from said bottom side for positioning in said locating holes.

3. The notebook computer as claimed in claim 2, wherein the number of said protruding positioning members is equal to the number of said locating holes.

4. The notebook computer as claimed in claim 1, wherein said top side of said display screen is smoothly chamfered.

5. The notebook computer as claimed in claim 1, wherein said display screen is turnable out of said recessed receiving open chamber to the outside of said cover shell and said base member.
